(19) United States
(12) Patent Application Publication
(10) Pub. No.: US 2025/0113512 A1
(43) Pub. Date: Apr. 3, 2025

(54) Power Semiconductor Device and Method of Producing a Power Semiconductor Device

(71) Applicant: Infineon Technologies AG, Neubiberg (DE)

(72) Inventors: Anton Mauder, Kolbermoor (DE); Hans-Jürgen Thees, Dresden (DE)

(21) Appl. No.: 18/897,117

(22) Filed: Sep. 26, 2024

(30) Foreign Application Priority Data
Sep. 29, 2023 (DE) 102023209627.7

(51) Int. Cl. H01L 29/739; H01L 29/06; H01L 29/16; H01L 29/66; H01L 29/78

(52) U.S. Cl. CPC H10D 12/441; H10D 12/032; H10D 30/0291; H10D 30/668; H10D 62/127; H10D 62/8325

(57) ABSTRACT

A method of producing a power semiconductor device includes: providing a semiconductor body with a vertically protruding fin covered by an insulation material covered by an electrode material, and an insulating material at least partially covering the electrode material; exposing a portion of the electrode material arranged above an upper portion of the fin; removing the exposed portion of the electrode material to expose the upper portion of the fin, thereby forming a respective recess adjacent to both sides of the exposed upper portion of the fin, the recesses being spatially confined by the insulation material, the electrode material and the insulating material; forming an ILD on top of the exposed portions of the device; and forming a first load terminal above the ILD and configured to contact the upper portion of the fin.

### TECHNICAL FIELD

This specification refers to embodiments of a power semiconductor device and to embodiments of a method of producing a power semiconductor device.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a forward load current along a load current path between two load terminals of the device. The load current is typically conducted by means of an active region of the power semiconductor device. The active region is typically surrounded by an edge termination region, which is terminated by an edge of the chip.

In case of a controllable power semiconductor device, e.g., a transistor, the load current path may be controlled by means of an insulated electrode, commonly referred to as gate electrode. For example, upon receiving a corresponding control signal, e.g., from a driver unit via a control terminal of the device, the control electrode may set the power semiconductor device in one of a forward conducting state and a blocking state.

Furthermore, some devices provide for reverse load current capability; i.e., the active region of the semiconductor body is further configured to conduct a reverse load current along a reverse load current path between the two load terminals of the device. For example, the RC (Reverse Current) IGBT is one representative of such devices. In an RC IGBT, a single chip unites an IGBT structure and a diode structure.

Irrespective of whether or not the device exhibits an RC configuration, it is generally an aim to design a power semiconductor device with high reliability and high efficiency. For example, in case of controllable devices, reliability may be reduced due to the risk of a breakdown because of an accidental electrical contact between one of the load terminals and the gate electrodes. These accidental contacts can occur due to a processing error during production of the device and/or due to device degradation over time. Even for device configurations with comparably small structures, such accidental contacts must be avoided to ensure a high device reliability.

### SUMMARY

According to an embodiment, a method of producing a power semiconductor device comprises: providing a semiconductor body with a vertically protruding fin covered by an insulation material covered by an electrode material, wherein an insulating material covers the electrode material at least partially; exposing a portion of the electrode material arranged above an upper portion of the fin; removing the exposed portion of the electrode material to expose the upper portion of the fin covered by the insulation material, thereby forming a respective recess adjacent to both sides of the exposed upper portion of the fin, said recesses being spatially confined by a) the insulation material, b) the electrode material and c) the insulating material; forming an interlayer dielectric, ILD, on top of the exposed portions of the device by a) chamfering edges of portions of the insulating material spatially confining said recesses, b) providing a further insulation material and c) a subsequent removal processing step to re-expose the upper portion of the fin without the insulating material covering the same; forming a first load terminal above the ILD, said first load terminal being configured to contact the upper portion of the fin.

According to a further embodiment, a power semiconductor device comprises: a semiconductor body with a vertically protruding fin configured to conduct a portion of the device's nominal load current; a first load terminal in contact with an upper portion of the fin; electrode material arranged adjacent to the fin and: electrically insulated from the fin based on insulation material; electrically insulated from the first load terminal based on an insulation structure. The insulation structure comprises an insulating material exhibiting a chamfered edge facing to the upper portion of the fin.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIGS. 1A-B both schematically and exemplarily illustrate a respective section of a vertical cross-section of a power semiconductor device in accordance with one or more embodiments;

FIGS. 2A-B both schematically and exemplarily illustrate a respective section of a vertical cross-section of a power semiconductor device in accordance with one or more embodiments;

FIG. 3 schematically and exemplarily illustrates a section of a vertical cross-section of a power semiconductor device;

FIG. 4 schematically and exemplarily illustrates a section of a vertical cross-section of a power semiconductor device in accordance with one or more embodiments; and

FIGS. 5-12 schematically and exemplarily illustrate, based on several sections of a vertical cross-section of a device being processed, a method of producing a power semiconductor device in accordance with some embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/dic. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor device is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “conducting state” of the power semiconductor device while a forward voltage bias is applied. A transition between the blocking state and the conducting state may be controlled by a control electrode or, more particularly, an electrical potential of the control electrode. Said electrical characteristics may, of course, only apply within a predetermined working range of the external voltage and the current density within the power semiconductor device. The term “blocking state” therefore may refer to conditions with the power semiconductor device being in the blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 500 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor based data processing.

For example, the power semiconductor device described below may be a single semiconductor chip, e.g., exhibiting a stripe cell configuration (or a cellular/needle cell configuration) and can be configured to be employed as a power component in a low-, medium- and/or high voltage application.

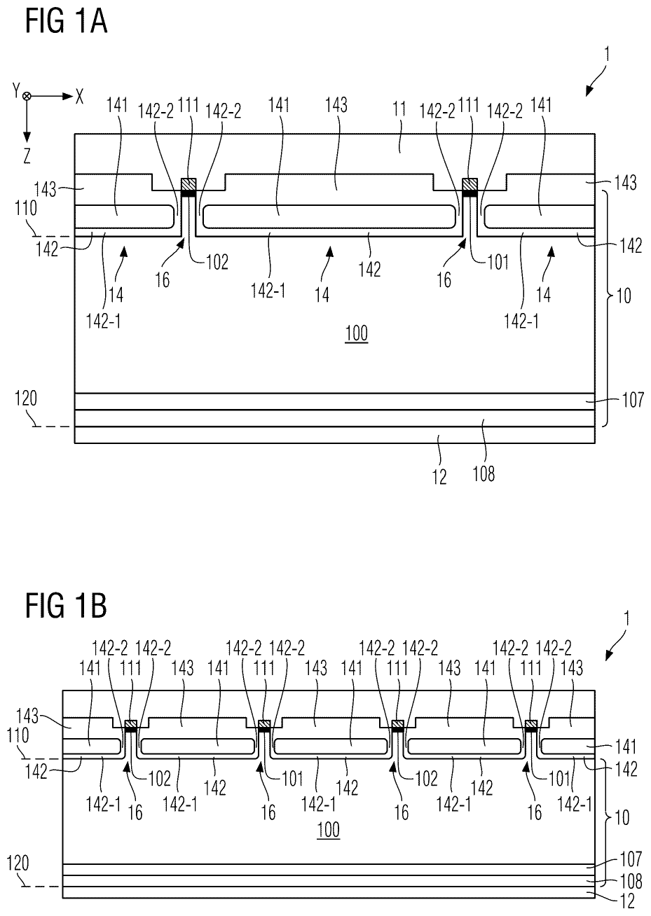

FIGS. 1A-B both schematically and exemplarily illustrate a respective section of a vertical cross-section of a power semiconductor device 1 in accordance with one or more embodiments. According to these embodiments, the power semiconductor device 1 exhibits an IGBT configuration.

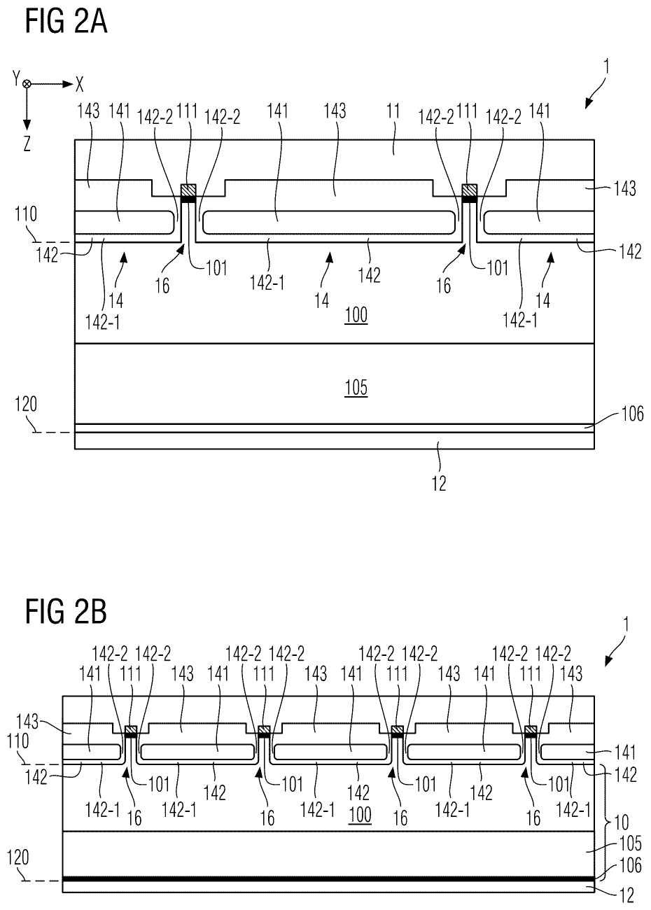

FIGS. 2A-B both schematically and exemplarily illustrate a respective section of a vertical cross-section of a power semiconductor device 1 in accordance with one or more other embodiments. According to these embodiments, the power semiconductor device 1 exhibits a MOSFET configuration.

The following description refers to each of FIG. 1A to FIG. 2B.

The power semiconductor device 1, herein also referred to as “device”, comprises, in a single chip, a semiconductor body 10 configured to conduct a load current between a first load terminal 11 at a first side 110 of the semiconductor body 10 and a second load terminal 12 at a second side 120 of the semiconductor body 10.

The first side 110 and the second side 120 may be arranged opposite of each other. E.g., the first side 110 is a front side of the device 1 and the second side 120 is a back side of the device 1. Accordingly, the device 1 may exhibit a vertical configuration according to which the load current within the device 1 follows a path in parallel to the vertical direction Z.

The device 1 further comprises a drift region 100 of a first conductivity type within the semiconductor body 10. Herein, the term “drift region” is employed with the meaning the skilled person typically associates therewith in the field of power semiconductor devices. For example, the vertical extension of the drift region 100 influences the voltage blocking capabilities of the device 1.

The device 1 further comprises fins 16 protruding from the first side 110 against the vertical direction Z. At least some of the fins 16 may be associated with respective control electrodes 141. Said at least some fins may be 16 may be associated with one or two respective control electrodes 141 each. This can be referred to as single sided configuration (with one associated control electrode 141 on only one side of the respective fin 16) or double sided configuration (with associated control electrodes 141 on both sides of the respective fin 16). Upon subjecting the control electrodes with a corresponding control signal, the device 1 may be set into the blocking state or into the conductive state. For example, to this end, the control electrodes 141 may be configured to induce or, respectively, cut-off conductive channels in the fins 16.

The control electrodes 141 are electrically isolated, at least based on an insulation structure 142, 143 from both the first load terminal 11 (and the second load terminal 12) and from the semiconductor body 10. The insulation structure 142 comprises a bottom insulating layer 142-1 electrically insulating the control electrode 141 from the semiconductor body and a gate insulating layer 142-2 electrically insulating the control electrode 141 from the fin 16. The gate insulating layer 142-2 may also be referred to as gate dielectric (layer).

The fins 16 are electrically connected with the first load terminal 11, e.g., based on contacts 111, as illustrated in FIGS. 1A-2B. These contacts 111 will be described in greater detail below. In a region where the fin 16 adjoins the contact 111, the fin may comprise a first doped region 101 of the first conductivity type or a second doped region 102 of the second conductivity type. In case of the IGBT configuration (cf. FIGS. 1A-B), both types (first doped region 101 of the first conductivity type and second doped region 102 of the second conductivity type) are realized; thereby, the device 1 exhibits a bipolar configuration. The ration between fins 16 of the first conductivity type (fins 16 comprising a first doped region 101) and fins 16 of the second conductivity type (fins 16 comprising a second doped region 102) may be at least 1 to 1, at least 1 to 3, or even at least 1 to 6. In other words, for every fin 16 comprising one of the first doped regions 101 there may be at least 1, at least 3, or even at least 6 fins 16 comprising one of the second doped regions 102. In case of the MOSFET configuration (cf. FIGS. 2A-B), the fins 16 may, for example, be provided only with the first doped regions 101 of the first conductivity type; thereby, the device 1 exhibits a unipolar configuration. Alternatively, it is possible also in case of a MOSFET configuration, that the device 1 comprises fins 16 of the first conductivity type (fins 16 comprising a first doped region 101) and fins 16 of the second conductivity type (fins 16 comprising a second doped region 102).

Furthermore, the device 1 may comprise a shield region of the second conductivity type buried in the semiconductor body 10 and spaced apart from the front side 110. Said shield region may be directly connected to the first load terminal 11 or be connected to the first load terminal 11 via one or more of the fins 16 of the second conductivity type (fins 16 comprising a second doped region 102). Two or more of said shield regions may form a JFET together.

Each of the fins 16 may be connected in parallel between the first load terminal 11 and the second load terminal 12, wherein each of the fins 16 can be configured to conduct a part of the load current between the first load terminal 11 and the second load terminal 12.

The drift region 100 is arranged below the fins 16; in other words, the drift region 100 is arranged below the front side 110 of the semiconductor body 10, whereas the fins 16 are arranged above the front side 110, in accordance with an embodiment. At the front side 110, the fins may adjoin the drift region 100 or another doped region below the front side 110 of the semiconductor body 10.

Due to the protruding fins 16 (e.g., characterized by their width being smaller than a lithography resolution used for forming them), the device 1 (in both the MOSFET and the IGBT configuration) may also be referred to as “FinFET controlled power transistor” due to the cell head that comprises “FinFET structures”. However, also the device 1 as a whole may be called “FinFET”. For example, the fins 16 may be characterized by a width being smaller than 100 nm.

The semiconductor body 10 at the back side 120 may be designed accordingly: In case of the IGBT configuration (cf. FIGS. 1A-B), the drift region 100 may adjoin a field stop region 107 of the first conductivity type, which may adjoin an emitter region 108 of the second conductivity type arranged in electrical connection with the second load terminal 12. The field stop region 107 of the first conductivity type exhibits a greater dopant concentration than the drift region 100, but typically a smaller total extension along the vertical direction Z as compared to the drift region 100, as illustrated. In case of the IGBT configuration (cf. FIGS. 1A-B), the drift region 100 may adjoin a buffer region 105 of the first conductivity type, which may adjoin a contact region 106 of the first conductivity type arranged in electrical connection with the second load terminal 12. The buffer region 105 of the first conductivity type exhibits a greater dopant concentration than the drift region 100, but typically a smaller total extension along the vertical direction Z as compared to the drift region 100, as illustrated. Furthermore, the contact region 106 of the first conductivity type exhibits a greater dopant concentration than the buffer region 105, but typically a smaller total extension along the vertical direction Z as compared to the buffer region 105, as illustrated.

The present disclosure relates to the configuration of the fins 16 and corresponding processing techniques, and in particular to the region where the fins 16 adjoin the first load terminal 11.

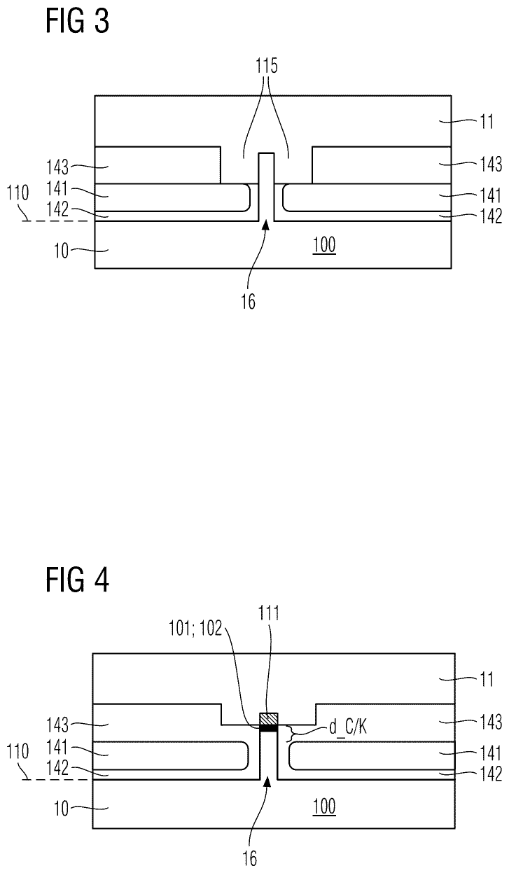

For example, referring to FIG. 3, a vertical FinFET pattern can be contacted by a contact hole 110 which is wider than the actual fin 16 in order to avoid issues with lateral misalignment and variations of the dimensions of the pattern of the contact hole etch. Due to vertical tolerances in the contact hole etch, the bottom of the contact hole 110 may reach the control electrode 141 thus producing an electrical short with the first load terminal 11. Even in case of no short, the depth variation of the contact hole 110 can lead to, larger device scattering, variation of the contact properties, or varying electrical properties.

For example, referring to FIG. 4, in case the top of the fin 16 which is embedded in the metal of the first load terminal 11 is fully silicided during formation of the contact 111, the actual contact interface will be the bottom of the silicided area/the contact 111. Thus, any scattering of the vertical distance d_C/K between the bottom of the silicided area/the contact 111 and the upper end of the first (or second) doped region 101 (or 102) may lead to scattering of the device performance.

To address the challenges described with respect to FIGS. 3 and 4, embodiments of a device production method are proposed herein. The devices 1 described above with respect to FIGS. 1A-2B may be produced according to one or more of the embodiments of the method described below with respect to FIGS. 5 to 12.

In accordance with one or more embodiments, it is proposed to use one or more etch stop layers to vertical self-align the lower end of the contact hole 110, i.e., the contact 111, to the upper end of the fin 16. Thereafter, the resulting contact may be used to define the position of the doped region 101, or respectively, the region 102 during the subsequent implantation step for the region 101, 102.

For example, cf. FIG. 5, in a first step 200 of an embodiment of the method, a semiconductor body 10 is provided with a vertically protruding fin 16 covered by an insulation material 142 covered by an electrode material 141, wherein an insulating material 143 covers the electrode material 141 at least partially. For example, a starting point may hence be the preparation of the control electrode 141, e.g., using thin gate layers as illustrated in FIG. 5. The insulating material 143 (e.g., based on SiO₂) may form a mask layer which may formed with an upper edge which is at the same level as the top of the gate layer. This may, e.g., be accomplished by using a thicker deposition and employing a subsequent chemical-mechanical polishing, CMP, processing step.

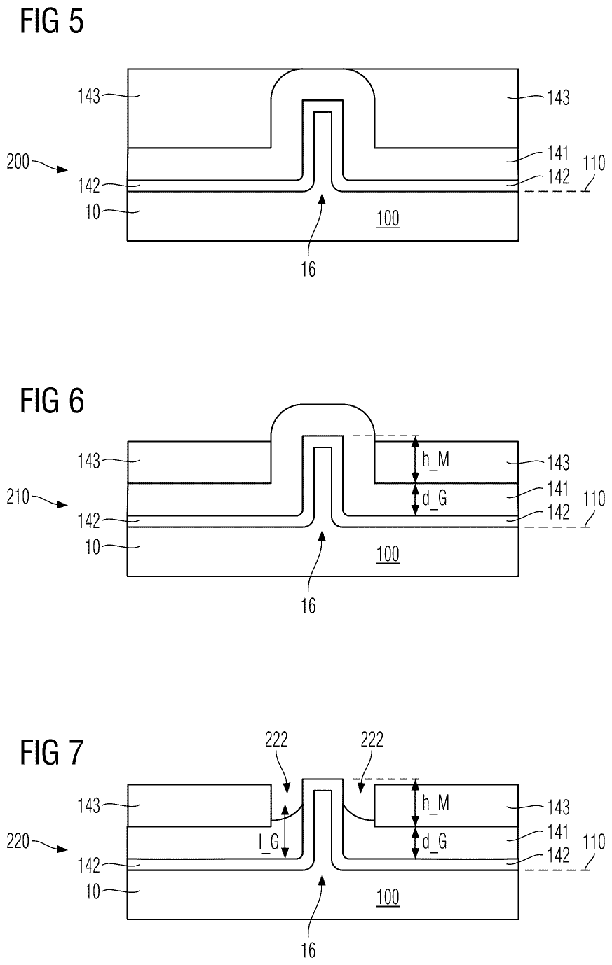

Subsequently, cf. FIG. 6, a portion of the electrode material 141 arranged above an upper portion of the fin 16 is exposed (step 210). For example, said mask layer is accordingly recessed to a level below the lower end of the gate layer on top of the fin 16, as indicated by the dashed line in FIG. 6. After step 210, both the control electrode 141 and the mask layer/insulating material 143 may exhibit defined thicknesses h_M and d_G, respectively.

After step 210, the vertical self-alignment can be implemented, e.g., as follows:

First, a step 220 of removing (cf. FIG. 7) the exposed portion of the electrode material 141 is carried out to expose the upper portion of the fin 16 covered by the insulation material 142, thereby forming a respective recess 222 adjacent to both sides of the exposed upper portion of the fin 16, said recesses 222 being spatially confined by a) the insulation material 142, b) the electrode material 141 and c) the insulating material 143. For example, the gate layer (electrode material 141) is recessed using isotropic etching in order to reach a desired channel length 1_G. The etching time may depend on the initial thickness h_M of the mask layer (insulating material 143), since the etching may be isotropic. However, also a combination of isotropic and anisotropic etch processes may be applied as long as they are highly selective to the chosen materials 142 and 143.

Accordingly, the electrode material removal step 220 may define said channel length 1_G at the fin 16, in accordance with an embodiment. Also, the electrode material removal step 220 can be based on an etch processing step. The etch processing step may be either an isotropic etch processing step, an anisotropic etch processing step, or a combination thereof.

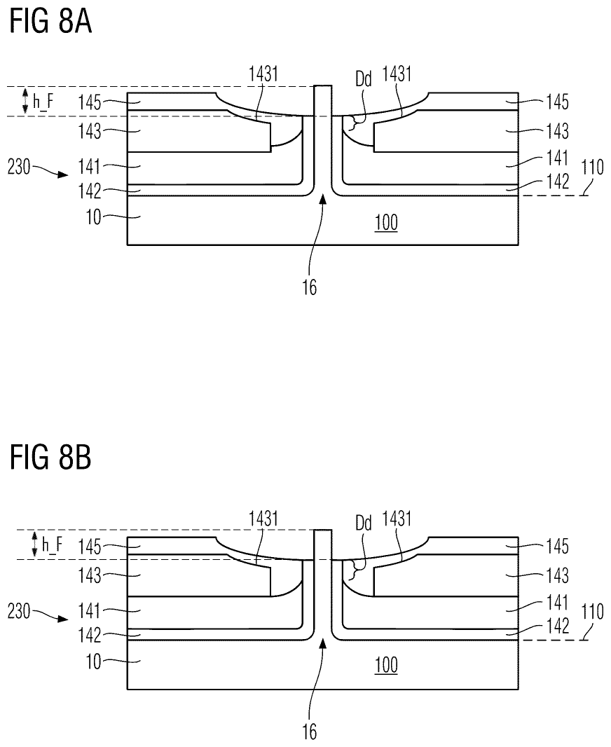

Then, in step 230, cf. FIGS. 8A and 8B, forming an interlayer dielectric, ILD, is carried out on top of the exposed portions of the device 1 by a) chamfering edges 1431 of portions of the insulating material 143 spatially confining said recesses 222, b) providing a further insulation material 145 and c) a subsequent removal processing step to re-expose the upper portion of the fin 16 without the insulating material 142 covering the same. Even though not clearly shown in FIGS. 1A-2B, said chamfered edges 1431 may also be present in the structures of FIGS. 1A-2B. The process block illustrated in FIG. 8A and FIG. 8B may comprise the deposition of the interlayer dielectric, ILD, using a high-density plasma, HDP, deposition process, e.g., for SiO₂. This oxide can be recessed, e.g., using isotropic etching (e.g., wet chemical etching) leading to a result as shown in FIG. 8A. The thickness of the ILD above the end of the gate layer (electrode material 141) or at the fin 16 can accordingly be defined by the deposition thickness of the ILD and the subsequent back etch step, and can thus be self-controlled. Small process variations in step 220 will cause I_G variations. As step 230 defines the recess of 145 from the top of the fin, the isolation thickness Dd will become larger if more electrode material 141 was removed (cf. FIG. 8B) and smaller in the opposite case (cf. FIG. 8A). The isolation thickness Dd between load terminal 11 on top and the upper end/portion of the fin 16 may, however, be varied based on 220, namely by the amount of removed electrode material 141, as illustrated based on the different isolation thicknesses Dd in FIGS. 8A and 8B. However, the constant exposed fin height (h_F) of the fin 16 over the insulating material 142 is a prerequisite for stable contact properties when the contact of the first doped regions 101 or second doped regions 102 to the first load terminal 11 is formed later. The variation of isolation thickness Dd needs to be accounted for by proper device design measures of the device 1. Furthermore, due to the exemplary combination of HDP oxide and the wet etch, the oxide shape is bowl-like, as illustrated in FIG. 8(A), which can be beneficial for later contact formation.

Thus, sub-steps a) and b) of the ILD forming step 230 are carried out simultaneously based on a high-density plasma, HDP, deposition processing step, in accordance with an embodiment. Furthermore, sub-step c) of the ILD forming step 230 can be based on an isotropic etch processing step. The ILD forming step 230 may lead to a defined thickness Dd of the ILD 145 covering the portion of the electrode material 141 Simultaneously, the ILD forming step 230 may lead to the defined fin height h_F of the fin 16 protruding over the ILD 145. In result, the ILD 145 may have the characteristic bowl shape. The ILD forming step 230 may lead to a minimum thickness Dd between the first load terminal 11 and the electrode material 141. Said minimum thickness Dd may be at least 20 nm or at least 50 nm.

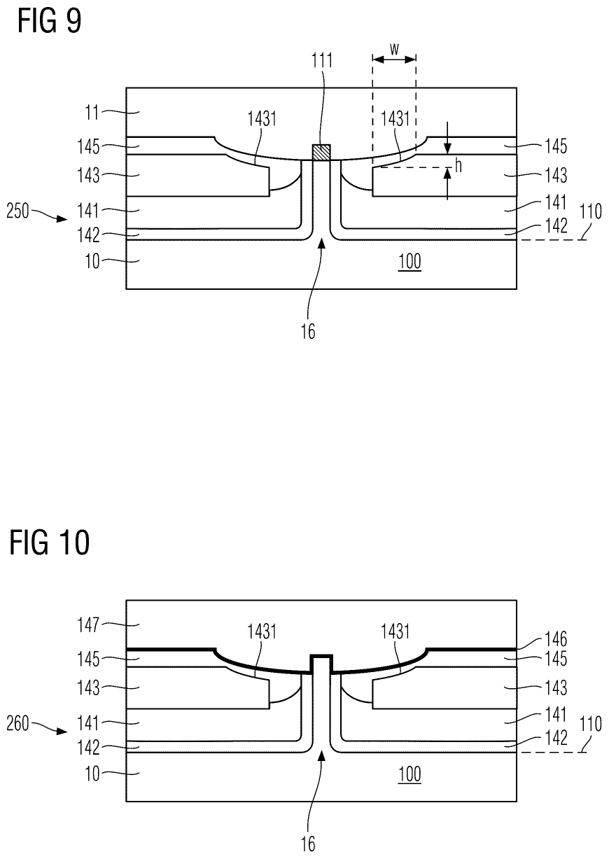

In a subsequent step 250 (or, respectively, 280), cf. FIG. 9 and FIG. 12, a first load terminal 11 may be formed above the ILD 145, said first load terminal 11 being configured to contact the upper portion of the fin 16.

Before formation of the first load terminal 11, the upper portion of the fin 16 may be subjected to at least one silicide formation processing step to form the contact 111. In addition, the first doped regions 101 and/or the second doped regions 102 may be formed in the fins 16 before formation of the first load terminal 11.

In some examples of the embodiments of the method described above, any contact hole lithography with small feature size or sophisticated contact hole fill can be avoided.

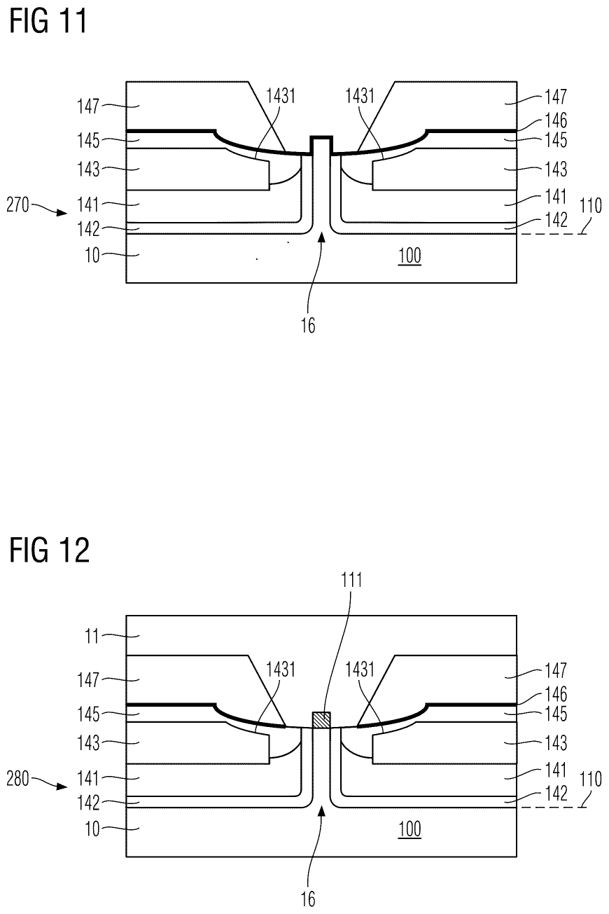

FIGS. 10 and 11 show another embodiment of the method. Before formation of the first load terminal 11 (as illustrated in FIG. 9), a further insulation structure is formed (step 260) by depositing an etch stop layer 146 on the ILD 145 and the exposed portion of the fin 16 and forming a further ILD 147 on the etch stop layer 146. Subsequently, cf. step 270 in FIG. 11, a portion of the further ILD 147 is removed to expose the upper portion of the fin 16. In a subsequent step 280, cf. FIG. 12, the first load terminal 11 may be formed above the ILD 145, said first load terminal 11 being configured to contact the upper portion of the fin 16.

The variant according to FIGS. 10 and 11 includes the recognition that several integrated power devices may require additional efforts in order to connect or isolate different device elements. The additional dielectric (oxide) layer, i.e., the further ILD 147 may be beneficial in this respect. Accordingly, first the etch stop layer 146, e.g., a silicon nitride layer, is deposited on the bowl-like surface illustrated in FIGS. 8A-B, followed by the further ILD 147, e.g., an oxide layer or a low-k layer. The further ILD 147 may have certain topology or may have an even surface as shown in FIG. 10, e.g., achieved by carrying out a CMP processing step. After performing, e.g., a contact hole lithography and an etch processing step, cf. FIG. 11, the etch step will vertically stop on the etch stop layer 146 providing sufficient process window to cope with eventual parameter scattering of layer deposition, CMP variations or fluctuations in the etching rate.

After selectively removing the etch stop layer 146 (in case of silicon nitride by using, e.g., hot phosphorous acid or a mixture of hydrofluoric acid and ethylene glycol) and a subsequent cleaning step, the contact hole can be filled in a conventional way, e.g., using a first metallic layer (e. g. Ti, Ta, Ni, Co, Pt) for providing a silicide on top of the fin 16, a barrier layer (e. g. TiN) and a plug, e. g. a W-Plug in addition to an upper metal layer. A possible result of these exemplary processing steps is schematically illustrated in FIG. 12.

Presented herein is also a power semiconductor device 1 that has been produced in accordance with one of the exemplary methods described above. I.e., as indicated above, the devices illustrated in FIGS. 1A to 2B may be equipped with said chamfered edges 1431.

For example, the power semiconductor device 1 according to the present disclosure comprises: a semiconductor body 10 with a vertically protruding fin 16 configured to conduct a portion of the device's nominal load current; a first load terminal 11 in contact with an upper portion of the fin; electrode material 141 arranged adjacent to the fin 16 and: electrically insulated from the fin 16 based on insulation material 142; electrically insulated from the first load terminal 11 based on an insulation structure. The insulation structure comprises an insulating material 143 exhibiting a chamfered edge 1431 facing to the upper portion of the fin 16.

For example, the chamfered edges 1431 in the insulating material 143 and a bowl-shape in the ILD 145 define both a) a vertical distance between contact 111 and the control electrode (Dd) 141 and b) the vertical extension of the first load terminal contact below the top of the fin (equivalent to h_F).

Regarding all embodiments, each of the fins 16 may have a width (along the first lateral direction X) of at least 20 nm and a height (along the vertical direction Z) of at least 0.25 μm. Further, each of the fins 16 may have a width of at most 100 nm and a height of at most 1 μm. The width of the fins 16 may be smaller than the lithography resolution being used during manufacture of the device 1.

Furthermore, the process for producing the device 1 is not intended to be used as process for forming memory or logic devices, but intended to be used for power semiconductor devices in a power application, such as a power converter. To this end, the device's nominal load current may amount to at least 5 A.

Each of the chamfered edges 1431 may extend along a width w amounting to a at least 50 nm and over a height h of at least 50 nm, cf. FIG. 9. Also, in an embodiment, each of the chamfered edges 1431 may exhibit a curved course, as illustrated in FIG. 9, for example.

The height h_F of the portion of fin 16 protruding over the ILD 145 may be at least 15 nm and at most 100 nm. The typical value may be around 50 nm.

In each of the described embodiments, the power semiconductor device 1 can be configured with a forward blocking voltage of at least 500 V.

Furthermore, in each of the described embodiments, the semiconductor body 10 of the power semiconductor device 1 may be based on silicon. In other embodiments, the semiconductor body 10 of the power semiconductor device 1 may be based silicon carbide SiC or another wide bandgap semiconductor material.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of producing a power semiconductor device, the method comprising:
providing a semiconductor body with a vertically protruding fin covered by an insulation material covered by an electrode material, wherein an insulating material covers the electrode material at least partially;
exposing a portion of the electrode material arranged above an upper portion of the fin;
removing the exposed portion of the electrode material to expose the upper portion of the fin covered by the insulation material, thereby forming a respective recess adjacent to both sides of the exposed upper portion of the fin, the recesses being spatially confined by the insulation material, the electrode material and the insulating material;
forming an interlayer dielectric (ILD) on top of the exposed portions of the device by chamfering edges of portions of the insulating material spatially confining the recesses, providing a further insulation material, and a subsequent removal processing step to re-expose the upper portion of the fin without the insulating material covering the upper portion of the fin; and
forming a first load terminal above the ILD, the first load terminal being configured to contact the upper portion of the fin.

2. The method of claim 1, wherein the chamfering and the providing the further insulation material are carried out simultaneously based on a high-density plasma (HDP) deposition processing step.

3. The method of claim 1, wherein the subsequent removal processing step is based on an isotropic etch processing step.

4. The method of claim 1, wherein the forming the ILD leads to a minimum thickness between the first load terminal and the electrode material.

5. The method of claim 1, wherein the forming the ILD leads to a bowl-formed trough, and wherein the fin protrudes from a bottom portion of the trough.

6. The method of claim 1, wherein the removing the exposed portion of the electrode material defines a channel length in the fin.

7. The method of claim 1, wherein the removing the exposed portion of the electrode material is based on an isotropic etch processing step.

8. The method of claim 1, further comprising:
subjecting the upper portion of the fin to a contact implantation processing step.

9. The method of claim 1, further comprising:
subjecting the upper portion of the fin to at least one silicide formation processing step.

10. The method of claim 1, further comprising:
forming a further insulation structure by depositing an etch stop layer on the ILD and the exposed portion of the fin, and forming a further ILD on the etch stop layer; and
removing a portion of the further ILD to expose the upper portion of the fin.

11. The method of claim 1, wherein the fin has a width of at least 20 nm and a height of at least 0.25 μm.

12. A power semiconductor device, comprising:
a semiconductor body with a vertically protruding fin configured to conduct a portion of a nominal load current of the power semiconductor device;
a first load terminal in contact with an upper portion of the fin; and
an electrode material arranged adjacent to the fin,
wherein the electrode material is electrically insulated from the fin by insulation material,
wherein the electrode material is electrically insulated from the first load terminal by an insulation structure,
wherein the insulation structure comprises an insulating material exhibiting a chamfered edge facing to the upper portion of the fin.

13. The power semiconductor device of claim 12, wherein the nominal load current amounts to a least 5A.

14. The power semiconductor device of claim 12, wherein the power semiconductor device is configured with a forward blocking voltage of at least 500 V.

15. The power semiconductor device of claim 12, wherein the power semiconductor device has a MOSFET or an IGBT configuration.

16. The power semiconductor device of claim 12, wherein the semiconductor body is based on silicon carbide (SiC).

17. The power semiconductor device of claim 12, wherein the chamfered edge exhibits a curved course.

18. The power semiconductor device of claim 12, wherein the semiconductor body comprises a frontside and a backside, wherein the fin protrudes form the frontside, and wherein the power semiconductor device further comprises a second load terminal at the backside.

19. The power semiconductor device of claim 18, wherein the semiconductor body further comprises a drift region between the first load terminal and the second load terminal.

20. The power semiconductor device of claim 18, wherein the fin is one out of a plurality of fins protruding at the frontside, wherein the fins are connected in parallel between the first load terminal and the second load terminal, and wherein each of the fins is configured to conduct part of a load current between the first load terminal and the second load terminal.
